(19) United States
(12) Patent Application Publication
(10) Pub. No.: US 2025/0044705 A1
(43) Pub. Date: Feb. 6, 2025

(54) METHOD FOR MEASURING THE ILLUMINATION PUPIL IN A SCANNER TAKING INTO ACCOUNT A MEASUREMENT RETICLE

(71) Applicant: Carl Zeiss SMT GmbH, Oberkochen (DE)

(72) Inventors: Robert BUSCHLINGER, Aalen Wasseralfingen (DE); Alexander WINKLER, Heidenheim (DE)

(21) Appl. No.: 18/920,238

(22) Filed: Oct. 18, 2024

Related U.S. Application Data
(63) Continuation of application No. PCT/EP2023/058644, filed on Apr. 3, 2023.

(30) Foreign Application Priority Data
Apr. 26, 2022 (DE) 10 2022 204 000.7

(51) Int. Cl. G03F 7/00

(52) U.S. Cl. CPC G03F 7/7025; G03F 7/70066; G03F 7/70133; G03F 7/70141; G03F 7/70158

(57) ABSTRACT

A method for characterizing a lithography apparatus, in particular, a method for characterizing a lithography apparatus configured to cause an obscuration of radiation, as well as a lithography apparatus and a computer program product configured to carry out the methods. A method for characterizing a lithography apparatus; detecting first diffracted radiation of the lithography apparatus, wherein the first diffracted radiation was diffracted at a characterization element; determining a diffraction property of the characterization element based on at least in part the first substantially undiffracted radiation and the first diffracted radiation.

### CROSS-REFERENCE TO RELATED APPLICATION

This is a Continuation of International Application PCT/EP2023/058644, which has an international filing date of Apr. 3, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2022 204 000.7 filed on Apr. 26, 2022.

### FIELD OF THE INVENTION

The present invention relates to a method for characterizing a lithography apparatus. In particular, the present invention relates to a method for characterizing a lithography apparatus configured to cause an obscuration of radiation, and to a lithography apparatus and a computer program product for carrying out the methods.

### BACKGROUND

In the semiconductor industry, increasingly smaller structures are produced on a wafer in order to ensure an increase in integration density. Among the methods used here for the production of the structures are lithography methods which image these structures on the wafer. The lithography methods may comprise e.g. photolithography, ultraviolet (UV) lithography, DUV lithography (i.e. lithography in the deep ultraviolet spectral range), EUV lithography (i.e. lithography in the extreme ultraviolet spectral range), x-ray lithography, etc.

The lithography apparatuses implementing the lithographic methods must usually meet stringent technical requirements in order to enable reliable imaging of the structures onto a wafer. To enable this, the optical properties and settings of a lithography apparatus must be reliably ensured during operation. Given the complex structure of a lithography apparatus, this usually requires a lithography apparatus to be characterized (optically) and for instance to be calibrated and/or adjusted. For example, this can be implemented at regular intervals alongside the operation of the lithography apparatus, or else in the context of a qualification, inspection or delivery.

In this regard, some lithography apparatuses might include lenses which comprise an obscuration. The obscuration can lead to a region of a pupil of the lens being blocked and/or shadowed (i.e. obscured). For example, the center of a pupil of a projection lens of a lithography apparatus might comprise the obscuration (e.g. on account of the optical structure of the projection lens, on account of an obscuration stop, etc.). The obscuration might enable e.g. a special type of lithographic exposure for imaging structures onto a wafer. However, the characterization of such lithography apparatuses might be made more difficult by the obscuration since e.g. a part of the pupil might be optically inaccessible.

DE 10 2018 207 384 A1 has disclosed a method for measuring an illumination system of a microlithographic projection exposure apparatus having a projection lens which comprises an obscuration in a pupil plane. The method includes the following steps: arranging a measurement structure with a pinhole in the region of a reticle plane of the projection exposure apparatus, creating a measurement radiation with the illumination system and radiating the measurement radiation at the measurement structure after this measurement radiation has passed through a pupil plane of the illumination system at a pupil position corresponding to the obscuration, with the measurement structure being configured to deflect the radiated—in measurement radiation such that this radiation at least in part runs past the obscuration in the pupil plane of the projection lens, and detecting the measurement radiation after it has run through the projection lens. An illumination property of the illumination system present during the exposure operation can be determined from the detected measurement radiation.

However, previous approaches to characterizing lithography apparatuses have not always led to an optimal characterization.

### SUMMARY

One object of the present invention is therefore to specify methods and apparatuses that improve the characterization of a lithography apparatus.

This and other objects are at least partly addressed or achieved by the various aspects of the present invention.

A first aspect relates to a method for characterizing a lithography apparatus configured to cause an obscuration of radiation. The method comprises: detecting a first substantially undiffracted radiation of the lithography apparatus; detecting a first diffracted radiation of the lithography apparatus, the first diffracted radiation having been diffracted at a characterization element. Further, the method comprises a determination of a diffraction property of the characterization element, based at least in part on the first substantially undiffracted radiation and the first diffracted radiation.

In this case, the characterization element can comprise an element which is used in known methods for characterizing the lithography apparatus. For example, the characterization element can enable an adaptation of a radiation of the lithography apparatus inaccessible to measurement technology (e.g. as a result of the obscuration) to form a radiation accessible to measurement technology (e.g. via diffraction, deflection, optical transformation, etc. at the characterization element) during the characterization. The adapted radiation (i.e. radiation accessible to measurement technology) can be used e.g. to calculate the radiation inaccessible to measurement technology, whereby a sufficient characterization of the lithography apparatus can be implemented. For example, the characterization of the lithography apparatus might comprise the characterization of one or more component parts (e.g. units and/or modules) of the lithography apparatus. In this case, the lithography apparatus described herein might also comprise a lithographic system, wherein the lithographic system may comprise a plurality of component parts (e.g. in the form of separate apparatuses). In this case, the component parts of the lithographic system can be coupled such that a lithographic method (e.g. for exposing a wafer) can be performed. Thus, in its totality, the lithographic system can be configured to operate like a lithography apparatus and may therefore e.g. also be considered as such. Accordingly, the characterization of the lithography apparatus can also comprise the characterization of the lithographic system as well as the (e.g. separate) characterization of the component parts of the lithographic system. In this case, the lithography apparatus (or the lithographic system) might comprise e.g. a source optical unit, an illumination unit and/or a projection lens. The source optical unit might comprise e.g. an optical unit which defines or adapts a beam source of a radiation of the lithography apparatus. The illumination unit might comprise an optical unit which adapts the radiation from the radiation source in order to direct this radiation e.g. purposefully at a mask plane (e.g. a reticle plane) of the lithography apparatus. The projection lens might comprise an optical unit which further adapts the radiation for the exposure of an exposure plane of the lithography apparatus.

Embodiments of the invention are based on an (optical) property of the characterization element, in particular the diffraction property of the characterization element, being determined with a radiation of the lithography apparatus itself. In this case, the diffraction property of the characterization element can be determined e.g. with radiation along an optical beam path of the lithography apparatus. Thus, this approach may represent an in situ determination of the diffraction property of the characterization element (i.e. within the lithography apparatus).

The characterization of (optical) properties or contributions of the characterization element in the lithography apparatus allows an optimal calculation of the radiation inaccessible to measurement technology and of the characterization or calibration of the lithography apparatus based thereon. In particular, these properties are then known for the conditions under which the characterization element can be used in the lithography apparatus (e.g. in the case of an installed characterization element within the lithography apparatus). The inventors have recognized that the (optical) properties of the characterization element or else of the lithography apparatus under real conditions might not necessarily be able to be derived from (e.g. externally determined) technical specifications since complex influences may decisively define the actual (optical) properties. For example, the characterization element might be subject to manufacturing tolerances, with the result that an actual (optical) property of the characterization element might vary. For example, the optical structure of the lithography apparatus might also be subject to manufacturing tolerances, whereby an (optical) property of the lithography apparatus might vary.

However, previous methods do not take the actually present (optical) properties of the characterization element, or of the lithography apparatus either, into account during the characterization of the lithography apparatus with a characterization element. However, non-consideration of these actual (optical) properties may lead to the characterization being based on incomplete assumptions, with the result that the lithography apparatus is characterized incorrectly. For example, in the known method described herein, the calculation of the radiation inaccessible to measurement technology may be based on incorrect assumptions with regards to the diffraction property. This may lead to the radiation inaccessible to measurement technology being determined incorrectly, whereby e.g. the lithography apparatus as well is characterized erroneously. This erroneous characterization may lead to an erroneous adjustment or calibration of the lithography apparatus, and this may adversely affect the quality of the lithographic method carried out by the lithography apparatus (and may e.g. be accompanied by high yield loss, a lengthy renewed adjustment/calibration, a reduction in the manufacturing capacity, etc.).

Not only have the inventors identified in more detail the herein-described mechanisms that influence the characterization element, but they have also identified how the characterization of the lithography apparatus can be optimized in this context.

On the one hand, the actual diffraction property of the characterization element can be determined or else verified (e.g. this can allow the determined diffraction property to in fact take account of a manufacturing variation of the characterization element present). On the other hand, the invention allows the diffraction property to be determined for the conditions under which the characterization element is used within the lithography apparatus. Accordingly, not only is it possible to use the method according to the invention to determine the actual diffraction property, but the influence of the lithography apparatus (e.g. an optical offset, an optical nonlinearity, etc.) and its interaction with the characterization element and the diffraction property are also taken into account. For example, this can prevent errors that are based on an incorrect consideration of the lithography apparatus.

For example, this relationship would not be possible in the case of an external (i.e. ex situ) determination of the diffraction property of the characterization element since, in this case, the diffraction property of the characterization element can at best be determined without the influence of the lithography apparatus. Accordingly, the external analysis might possibly lead to an incorrect characterization of the lithography apparatus. Hence, the invention can make it possible to manage without a complex external characterization element analysis which cannot take account of the influence of the lithography apparatus under the actual conditions. For example, it is possible to manage without a detailed measurement of the actual structure of the characterization element, which also detects manufacturing faults, and without a (rigorous) simulation, based thereon, of the corresponding diffraction property. It is also possible to manage without the measurement of the characterization element on an external diffraction measurement stand. Accordingly, the invention can make it possible to manage without an external analysis of the diffraction property using external (e.g. expensive) apparatuses and additional complicated measurements.

According to further embodiments of the invention, the diffraction property is determined in this case (at least in part) on the basis of a substantially undiffracted radiation and a diffracted radiation. The first substantially undiffracted radiation described herein may comprise a radiation of the lithography apparatus which does not experience or has not experienced significant diffraction. For example, this may correspond to a radiation which, according to the optical design of the lithography apparatus, is shaped such that its diffraction appearance (e.g. an interference pattern) is substantially not present, is minimized and/or represents no purposeful technical effect for the exposure radiation of the lithography apparatus. For example, the radiation of the lithography apparatus incident on an exposure plane (e.g. on a wafer plane) can be referred to as exposure radiation. In an example, the first substantially undiffracted radiation may comprise a substantially undiffracted radiation delimited in beam cross section by a stop. This example assumes that the diffraction appearance possibly caused by the stop essentially does not get transferred to the exposure radiation (instead, the stop mainly fulfills the purpose of limiting the beam cross section). For example, this can be implemented by separating the length scales of the radiation and the stop. For example, the radiation might comprise a wavelength in the nanometer range and the stop might comprise a dimension (e.g. a diameter and/or a radius of the stop) in the millimeter to meter range. The first substantially undiffracted radiation may e.g. correspond to a radiation emitted from a beam source (e.g. from a source optical unit of the lithography apparatus) and/or from an illumination unit of the lithography apparatus.

The first diffracted radiation described herein may comprise a radiation of the lithography apparatus which was exposed to diffraction at the characterization element. The first diffracted radiation can have a diffraction appearance associated with the characterization element (e.g. a diffraction image, an interference image, etc.). For example, the first diffracted radiation can have a plurality of locally delimited diffraction maxima which make up a part of the diffraction appearance. For example, the diffraction maxima can be associated with an order of diffraction of the diffracted radiation resulting from the diffraction at the characterization element. For example, the first diffracted radiation may comprise diffraction maxima which correspond to a zeroth order of diffraction, a (plus) first order of diffraction and/or a minus first order of diffraction. Further, all further orders of diffraction of the diffracted radiation are also conceivable (e.g. at least one of the following orders of diffraction: plus and/or minus second order of diffraction, plus and/or minus third order of diffraction, plus and/or minus fourth order of diffraction, etc.).

In an example, the first substantially undiffracted radiation and the first diffracted radiation are associated with one another. For example, the first substantially undiffracted radiation and the first diffracted radiation may emerge from the same beam source (with substantially the same configuration of the beam source) or may in part have the same beam path (e.g. upstream of the region of incidence of the characterization element). For example, the first substantially undiffracted radiation can be radiated into a specific optical path of the lithography apparatus such that it can be detected e.g. at a detection plane. In this example, the first substantially undiffracted radiation can also be radiated into the same specific optical path in which the characterization element, however, is arranged. In this case, the first substantially undiffracted radiation is exposed to the characterization element and diffracted. This diffracted radiation emerging from the characterization element may correspond to the first diffracted radiation and e.g. may be detected at the same detection plane. Accordingly, the first diffracted radiation may correspond to the part of the first substantially undiffracted radiation which, if the characterization element is present, is diffracted out of the latter.

Accordingly, the diffraction property of the characterization element can be deduced with the first diffracted radiation and the first substantially undiffracted radiation (associated therewith). For example, the detected first diffracted radiation (emerging from the characterization element) and the detected first substantially undiffracted radiation (present without the characterization element) can be related to one another such that the diffraction behavior (e.g. the diffraction property) at the characterization element can be determined sufficiently.

Further, another aspect relates to the lithography apparatus not necessarily being configured to cause an obscuration of the radiation. For example, the diffraction property of a characterization element can also be determined within a lithography apparatus which is not configured to cause an obscuration (as described herein) of radiation.

In a further example, however, the lithography apparatus can be configured such that a subset of the first substantially undiffracted radiation is exposed to the obscuration and hence forms an obscured subset. For example, a part of the first substantially undiffracted radiation can be covered or shadowed by the obscuration. For example, the obscured subset of the first substantially undiffracted radiation cannot be detected as a result. Accordingly, the obscured subset can be considered to be a part of the first substantially undiffracted radiation inaccessible to measurement technology. For example, the obscuration of the lithography apparatus can be used in the event of exposure within the scope of a dark-field illumination mode. In this case, the obscuration of the lithography apparatus can have any geometry and position such that the obscured subset accordingly can make up any desired geometry and position within the (detected) first substantially undiffracted radiation. In an example, the entire first substantially undiffracted radiation can be exposed to the obscuration such that the obscured subset may comprise the entire first substantially undiffracted radiation (e.g. in a specific plane of the lithography apparatus). In other examples, the obscured subset is a proper subset of the first substantially undiffracted radiation.

In a further example, the lithography apparatus can be further configured such that a subset of the first diffracted radiation is not exposed to the obscuration and hence forms an unobscured subset. For example, a part of the first diffracted radiation may comprise a beam path which passes the obscuration and thus forms the unobscured subset. For example, the unobscured subset can thus be detected as it is not incident on the obscuration. In this context, the unobscured subset can be considered to be accessible to measurement technology. In an example, a part of the first diffracted radiation can likewise be exposed to the obscuration of the lithography apparatus and e.g. be covered or shadowed by the obscuration (and hence not be detected, for example). The obscuration of the first diffracted radiation can likewise make up (depending on the configuration of the obscuration of the lithography apparatus) any desired geometry and position within the (detected) first diffracted radiation. In an example, the (detected) first diffracted radiation (e.g. the unobscured subset in particular) can be limited by the numerical aperture of the lithography apparatus. For example, a few diffraction maxima (or else orders of diffraction) of the first diffracted radiation cannot be detected on account of the limitation of the numerical aperture.

In a further example, the determination of the diffraction property is also based on a compensation. In this case, the compensation can comprise e.g. any desired compensation calculation based on a mathematical optimization method. For example, an unknown parameter (e.g. based on inaccessible information in the detected first substantially diffracted radiation and/or in the first diffracted radiation) might be present when determining the diffraction property. The unknown parameter can be determined or estimated through the compensation. Consequently, complete information or a sufficient diffraction property can nevertheless be deduced, for example, from a data record with inaccessible information. For example, the compensation may comprise a compensation of the diffraction property and/or the detected first substantially undiffracted radiation and/or the detected first diffracted radiation (for example since corresponding parameters might be unknown).

In a further example, the method comprises the compensation compensating an appearance of the diffraction property associated with the obscuration. For example, inaccessible information in the detected first substantially diffracted radiation and/or in the first diffracted radiation may occur as a result of the obscuration such that some values of the diffraction property cannot be determined. This may be caused by the obscured subset of the first substantially undiffracted radiation, or else by the obscuration of the first diffracted radiation. As described herein, certain values cannot be detected for both types of radiation as a result of the obscuration, and so some values of the first substantially undiffracted radiation and/or of the first diffracted radiation (associated therewith) are undefined. No diffraction property can be determined (directly) for these undefined values, and so the diffraction property is likewise undefined at the corresponding locations. The appearance of the diffraction property associated with the obscuration might in this case comprise an appearance (e.g. missing data points, a data record, a geometry, etc.) of the undefined diffraction property. Thus, there is a compensation of the diffraction property for its undefined values according to the invention.

In an example, the compensation comprises an interpolation and/or an extrapolation.

In an example, the method comprises the diffraction property being based at least in part on a relationship between the first diffracted radiation and the first substantially undiffracted radiation.

In an example, the diffraction property comprises a diffraction efficiency of the first diffracted radiation in relation to the first substantially undiffracted radiation in an angular space. In this case, the diffraction efficiency can be based on the relationship of the first diffracted radiation to the first substantially undiffracted radiation. In this case, the angular space can be spanned over a vector space of wave vectors (e.g. over kx, a wave vector for the x-coordinate, and ky, a wave vector for the y-coordinate). The representation in angular space can enable the suitable representation of angle-dependent diffraction efficiencies. In this case, compensating (e.g. extrapolating) the diffraction efficiency for certain regions of the angular space (which are not obscured) allows reliable determination of the diffraction efficiency for other (e.g. obscured) regions of the angular space as well. Further, a diffraction efficiency in angular space can be determined e.g. for different field points of the characterization structure.

In an example, the detection of the first substantially undiffracted radiation comprises a detection of an intensity of the first substantially undiffracted radiation in a pupil of the lithography apparatus. In addition to that or in an alternative, the detection of the first diffracted radiation can comprise a detection of an intensity of the diffracted radiation in the pupil. For example, the pupil may comprise an exit pupil of the lithography apparatus. In this case, the exit pupil may represent an exit angular space of the lithography apparatus (or else of the characterization element). For example, detection can be implemented in a plane (i.e. a detection plane) which is offset vis-à-vis the focal plane of the exposure radiation (e.g. a wafer plane). For example, this offset can allow the exit angular space to be detected in the pupil with a radiation detector (e.g. a CCD sensor). However, it is also conceivable that the detection can take place in any other desired plane of the lithography apparatuses (e.g. also in the wafer plane).

In an example, the first substantially undiffracted radiation comprises a plurality of first substantially undiffracted radiation beams; wherein the first diffracted radiation comprises a plurality of first diffracted radiation beams, each of which was diffracted at the characterization element. In this case, the radiation beams can also be considered to be radiation channels of the lithography apparatus and may emerge from e.g. the structure of the illumination unit of the lithography apparatus. For example, the illumination unit may comprise a plurality of facet mirrors, wherein each facet mirror can be associated with a radiation beam. With the setting of the facet mirrors, the radiation beams (e.g. created in the illumination unit) can be radiated independently of one another in an optical path of the lithography apparatus in the various settings. In this case, the facet mirrors can be arranged in the style of a matrix (e.g. in an array arrangement), wherein each facet mirror can be addressed separately in order to radiate each radiation beam associated with the facet mirror into the optical path of the lithography apparatus. A certain number of radiation beams based e.g. on a specific set of facet mirrors from the matrix arrangement and also on further (optical) settings (e.g. a specific tilt/deflection of the facet mirrors, etc.) are usually used during lithographic exposure. In this context, the plurality of first substantially undiffracted radiation beams can be configured such that they correspond to a setting of the radiation beams during the lithographic exposure (e.g. in the case of the dark-field illumination). The plurality of first diffracted radiation beams may in this case correspond to the diffracted radiation beams corresponding to a diffraction of the respective radiation beam from the plurality of first substantially undiffracted radiation beams. As described herein, the first substantially undiffracted radiation and the first diffracted radiation may be associated via the diffraction at the characterization element, with this assignment likewise applying correspondingly to the plurality of radiation beams. Thus, firstly, a plurality of first substantially undiffracted radiation beams (e.g. a plurality of intensity spots) are detected in the detection plane with the irradiation with radiation beams. Further, for a substantially undiffracted radiation beam, the corresponding first diffracted radiation beams (e.g. of zeroth order of diffraction, plus first order of diffraction, minus first order of diffraction) can be detected in the detection plane in each case. Hence, when detecting the diffracted radiation, very different diffraction maxima may arise in the detection plane for each of the first substantially undiffracted radiation beams. In this context, the lithography apparatus settings can be chosen such that e.g. the diffraction maxima do not overlap, with the result the radiation beams can be assigned to one another.

As a result of the obscuration of the lithography apparatus, one or more first substantially undiffracted radiation beams, and also one or more first diffracted radiation beams, might be analogously obscured or shadowed, whereby these can no longer be detected.

In an example, the method comprises the determination of the diffraction property comprising a determination of at least one order of diffraction of the first diffracted radiation. This can enable an order of diffraction-specific analysis of the first diffracted radiation. In this context, this information can be used for the (order of diffraction-specific) determination of the diffraction property. For example, determining at least one order of diffraction of the first diffracted radiation may comprise determining the index of the at least one order of diffraction of the first diffracted radiation (e.g. the index can specify the order of the order of diffraction; thus, it is e.g. possible to determine which order of diffraction is present for the diffracted radiation, e.g. it is possible to determine whether this is the zeroth, the plus first or the minus first order of diffraction).

In an example, the method comprises the order of diffraction being determined for at least one first diffracted radiation beam from the plurality of first diffracted radiation beams. This information can be used for the determination of the diffraction property. In this case, the at least one first diffracted radiation beam can be detected e.g. in the form of a locally delimited beam distribution (e.g. a local intensity spot). Further, the order of diffraction can be determined for each diffracted radiation beam (or else for a specific number thereof), with the result that the corresponding order of diffraction (e.g. the index of the order of diffraction) is determined for each locally delimited beam distribution (e.g. for each local intensity spot) of the detected first diffracted radiation which is associated with a diffraction maximum of a diffracted radiation beam. In this case, the order of diffraction may comprise at least one of the following: zeroth order of diffraction, plus first order of diffraction, minus first order of diffraction, second order of diffraction, minus second order of diffraction.

In an example, the method comprises a corresponding first substantially undiffracted radiation beam from the plurality of first substantially undiffracted radiation beams being determined for the at least one first diffracted radiation beam. Hence, the at least one first diffracted radiation beam can be assigned its respective radiation beam from the first substantially undiffracted radiation which has not experienced diffraction at the characterization element. Further, the corresponding undiffracted radiation beam can be determined and assigned for each diffracted radiation beam (or else for a specific number thereof). Hence, for example, the diffracted intensity spots (i.e. the diffracted radiation beams of the first diffracted radiation) can be assigned to the corresponding intensity spots of the first substantially undiffracted radiation (i.e. the corresponding substantially undiffracted radiation beams of the first substantially undiffracted radiation). Accordingly, each diffracted intensity spot or each detected first diffracted radiation beam (of any desired order of diffraction) can be related to the corresponding undiffracted intensity spot or to the corresponding detected first substantially undiffracted radiation beam.

Further, a corresponding diffracted radiation beam can also be assigned to another order of diffraction, e.g. also for the at least one diffracted radiation beam. Hence, for example, all detected radiation beams (whether diffracted or undiffracted) can be related to one another.

In an example, the method comprises the diffraction property being determined for the at least one first diffracted radiation beam. Further, the diffraction property can be determined for at least one first diffracted radiation beam of at least one order of diffraction. Further, the diffraction property can be determined for each diffracted radiation beam (or else for a specific number thereof). Spoken figuratively, a first grid of diffracted radiation beams can be detected in the detection plane in the event of a plurality of diffracted radiation beams. The orders of diffraction of the diffracted radiation beams are determined, with the result that the diffracted radiation beams can be grouped according to their corresponding orders of diffraction. Thus, a second grid of diffracted radiation beams arises for each group of an order of diffraction. For each second grid, the corresponding diffraction property (as described herein) can be determined for each diffracted radiation beam.

In an example, the method also comprises a determination of at least one part of the obscured subset, based at least in part on the diffraction property and the first diffracted radiation. With the determined diffraction property, the invention can enable a reconstruction of a part of the first substantially undiffracted radiation. As emerges from the examples described herein, the diffraction property can be determined in full even though there are undefined values in the diffracted and/or undiffracted radiation, e.g. as a result of the obscuration. Hence, a diffraction property can also be determined for the first diffracted radiation in relation to the first substantially undiffracted radiation of the obscured subset. Hence, information about the diffraction property may be available in the region of the obscured subset. In the context of a corresponding first diffracted radiation, it is consequently possible to deduce the obscured subset, for example since it is only the obscured subset that is unknown, but not its diffraction property. This can enable a determination of the obscured subset (e.g. by virtue of the relationship of the first diffracted radiation to the diffraction property).

In an example, the determination of the obscured subset part is also based at least in part on the part of the unobscured subset which is associated via an order of diffraction with the part of the obscured subset. As described herein, the first diffracted radiation can correspond to the diffraction of the first substantially undiffracted radiation at the characterization element. Accordingly, this example is based on the fact that although a radiation of the obscured subset cannot be detected, a radiation of an order of diffraction of the obscured subset can be radiated past the obscuration with a diffraction of the first substantially undiffracted radiation at the characterization element. Accordingly, a certain part of the unobscured subset of the first diffracted radiation is associated with a part of the obscured subset of the first substantially undiffracted radiation. Accordingly, the obscured subset can be determined by virtue of the unobscured subset associated therewith and its diffraction property being used. In this case, the obscured subset can be determined e.g. through the relationship of the unobscured subset to the diffraction property.

In an example, the determination of the obscured subset part further comprises a determination of at least one first substantially undiffracted radiation beam comprised in the obscured subset, based at least in part on a corresponding first diffracted radiation beam of at least one order of diffraction comprised in the unobscured subset. This example takes account of the fact that initially there is no information available about the radiation beams in the obscured subset as these cannot be detected but only be determined. For example, this can be implemented on the basis of the first diffracted radiation beams which are not exposed to the obscuration and can be detected. When assigning the first diffracted radiation beams to the corresponding first substantially undiffracted radiation beams, it might be possible to determine that, for example, an assignment to a first substantially undiffracted radiation beam is not possible on account of the obscuration. Accordingly, the evaluation of the detectable diffracted and corresponding undiffracted radiation beams can be used to deduce the first substantially undiffracted radiation beams in the obscured subset with a suitable model. For example, the latter may comprise the number, position, and/or arrangement of the undiffracted radiation beams in the obscured subset.

In an example, the determination of the part of the obscured subset further comprises a determination of an intensity of the at least one first substantially undiffracted radiation beam based at least in part on the diffraction property and the intensity of the corresponding first diffracted radiation beam. Accordingly, the intensity of a first substantially undiffracted radiation beam comprised in the obscured subset can be implemented via the diffraction property of the corresponding first diffracted radiation beam and its detected intensity. In an example, the detected intensity of the first diffracted radiation beam can be denoted by I1 and its diffraction efficiency by eff1. Hence, an intensity of the corresponding first substantially undiffracted radiation beam Iu can emerge from I1/eff1 (e.g. Iu=I1/eff1).

Additionally, a further aspect of the method relates to the circumstances described herein in relation to the determination of the obscured subset also being able to be used to determine an (e.g. substantially undiffracted) radiation which is located outside of the numerical aperture (and hence e.g. cannot be detected with a detector). In this exemplary aspect, this (e.g. substantially undiffracted) radiation inaccessible to measurement technology thus is caused by the limitation of the numerical aperture (i.e. the (e.g. substantially undiffracted) radiation inaccessible to measurement technology is obscured by the numerical aperture in this case). The circumstances described herein in relation to the unobscured subset can be applied to the corresponding (diffracted) radiation located within the numerical aperture (and hence e.g. can be detected). The corresponding (diffracted) radiation would thus be accessible to measurement technology in this case. Hence, according to the aspects described herein, the (substantially undiffracted) radiation located outside of the numerical aperture can be calculated with the (diffracted) radiation located within the numerical aperture.

In an example of the method, the latter furthermore comprises: detecting a second substantially undiffracted radiation of the lithography apparatus; detecting a second diffracted radiation of the lithography apparatus, the second diffracted radiation having been diffracted at the characterization element; determining a subset of the second substantially undiffracted radiation which is exposed to the obscuration, based at least in part on the diffraction property and the second diffracted radiation.

For example, it might be necessary during the operation of the lithography apparatus to determine the substantially undiffracted radiation of the lithography apparatus at time offset intervals, e.g. to use this to calibrate the lithography apparatus. For example, (optical) settings of the lithography apparatus might change or drift during operation (or following transportation), and so the actual value of the substantially undiffracted radiation also changes. Therefore, it might be necessary to determine the substantially undiffracted radiation at different times (for example at a first time for the first radiation and at a later second time for the second radiation). The substantially undiffracted radiation which is not detected for the purpose of determining the diffraction property can in this case be considered to be the second substantially undiffracted radiation. As described herein, the obscuration of the lithography apparatus may in this case analogously lead to a subset of the second substantially undiffracted radiation being obscured and e.g. not being detected. According to the invention, as described herein for the obscured subset of the first substantially undiffracted radiation, it is possible in this case to resort to the (e.g. previously) determined diffraction property of the characterization element in order to determine the subset of the second substantially undiffracted radiation exposed to the obscuration. To this end, a corresponding second diffracted radiation is detected (as described analogously herein for the obscured subset). The corresponding second diffracted radiation can be used to determine the subset of the second substantially undiffracted radiation, which is exposed to the obscuration, with the relation to the determined diffraction property. In this context, the assumption can be made that the diffraction property of the characterization element has not changed (significantly). However, it is also conceivable in this context that the diffraction property of the characterization element (as described herein) can optionally be redetermined. The features and examples for the first substantially undiffracted radiation specified herein can also apply to the second substantially undiffracted radiation, and vice versa. Likewise, the features and examples for the first diffracted radiation specified herein can also apply to the second diffracted radiation, and vice versa.

In an example, the method comprises the second substantially undiffracted radiation being associated with a beam path of the first substantially undiffracted radiation, with the second diffracted radiation being associated with a beam path of the first diffracted radiation. In this case, the beam path can correspond to an optical setting, from which a defined profile of the substantially undiffracted radiation arises (e.g. a specific beam angle, beam cross section). Accordingly, a temporal change or drift of this optical setting can be determined in this example, since the first and second substantially undiffracted radiation can be determined e.g. for an equivalent optical property (e.g. the same beam source). However, it is also conceivable that the second substantially undiffracted radiation emerges from a different beam path (e.g. a different beam source, from a different optical setting, etc.).

In an example, the method further comprises an adjustment of an element for emitting radiation of the lithography apparatus, based at least in part on the determination of the obscured subset of the first substantially undiffracted radiation (as described herein) and/or the determination of the subset of the second substantially undiffracted radiation (as described herein). The invention enables a complete reconstruction of the substantially undiffracted radiation since even the obscuration-exposed radiation of the substantially undiffracted radiation (as described herein) can be determined. Hence, complete information regarding the substantially undiffracted radiation can be available, as if the lithography apparatus were to cause no obscuration. Accordingly, the complete information regarding the substantially undiffracted radiation can be used not only for characterizing the lithography apparatus but also for adapting its settings (e.g. in order to obtain a desired target value of the substantially undiffracted radiation). In this case, the adaptation may comprise e.g. an adjustment and/or a calibration of radiation emitting element. The radiation emitting element may in this case comprise an illumination unit (as described herein) of the lithography apparatus. For example, the adaptation may comprise an adjustment of a facet mirror of the illumination unit (e.g. an adaptation of the alignment/tilt of a facet mirror).

In an example, the method comprises the characterization element being arranged in a reticle plane of the lithography apparatus. Thus, the characterization element can be arranged in the same plane as a reticle to be exposed using the lithography apparatus. For example, the characterization element can be arranged on a reticle, with the result that the diffracted radiation can be created in suitable fashion.

In an example, the characterization element comprises a diffraction structure. The diffraction structure may comprise at least one of the following: diffraction grating, phase grating, amplitude grating, reflection grating, blazed grating.

In an example, the obscuration is associated with a radiation projecting element of the lithography apparatus and/or an obscuration stop of the lithography apparatus. The radiation projecting element can comprise e.g. a projection lens of the lithography apparatus (e.g. to project the radiation onto a wafer plane). For example, the obscuration may be caused by the optical beam path of the projection lens of the lithography apparatus. In this case, the projecting element may comprise e.g. a mirror optical unit which causes an obscuration of the radiation. For example, the obscuration stop can be arranged within the radiation projecting element. For example, the obscuration stop may comprise an absorbing material capable of absorbing the lithography apparatus radiation such that this is obscured accordingly. Further, the obscuration stop might also be arranged in other optical planes of the lithography apparatus.

In an example, the obscuration comprises a central obscuration of radiation. In the case of a central obscuration, e.g. the center of the pupil of the lithography apparatus is obscured, with e.g. a peripheral region of the pupil not being obscured.

In an example, the first substantially undiffracted radiation comprises a radiation reflected at a reticle plane of the lithography apparatus. In an alternative to that or in addition, the first diffracted radiation comprises a radiation diffracted at the reticle plane. For example, the radiation path of the first substantially undiffracted radiation can be optically reflected in the reticle plane by a mirror or a mirror structure. For example, the mirror structure may comprise a structure without diffractive properties or an isolated reflective structure (which can be referred to as e.g. a pinhole). The mirror structure, and also the characterization element, may in this case be comprised on a reticle which is arranged in the reticle plane for the method.

In a further example, the invention comprises a method of lithographic processing of a semiconductor-based wafer comprising: a lithographic transfer of a pattern associated with a lithographic object (e.g. a reticle, a lithographic mask, etc.) onto the wafer by a lithography apparatus able to obscure a radiation characterized using the method described herein. The invention allows even obscuration-causing lithography apparatuses to be characterized sufficiently (i.e. even in the region of the obscuration), with the result that the quality of the mask exposure on the wafer can be significantly optimized.

A second aspect of the invention relates to a lithography apparatus comprising: a radiation detecting element; a diffraction property determining element of a characterization element, wherein the lithography apparatus is configured to perform one of the methods described herein. The radiation detecting element may comprise e.g. a radiation detector (e.g. a sensor, e.g. a CCD sensor). The diffraction property determining element may comprise e.g. a computing unit, a computer system, a computer apparatus, etc.

The lithography apparatus may comprise an EUV lithography apparatus, the radiation of which includes a radiation in the extreme ultraviolet spectrum of the wavelength. In this case, the lithography apparatus can be configured e.g. for a radiation of the order of 13.5 nm.

In an example, the lithography apparatus described herein is configured to automatically carry out the method according to any of the examples mentioned herein.

A third aspect relates to a computer program comprising instructions which, when executed by a computer apparatus and/or a lithography apparatus, cause the computer apparatus and/or the lithography apparatus to carry out a method of the first aspect.

The method also relates to a lithography apparatus comprising a memory containing a computer program described herein. Alternatively, it is also possible for the computer program to be stored elsewhere (e.g. in a cloud) and for the lithography apparatus to merely have an instruction receiving element that arises from executing the program elsewhere. Either way, this may allow the method to run in automated or autonomous fashion within the apparatus. Consequently, it is possible to minimize the intervention, e.g. by an operator, and so it is possible to minimize both the costs and the complexity when characterizing lithography apparatuses.

The features (and also examples) of the methods specified herein may also be applied or applicable correspondingly to the (lithography) apparatus mentioned or the computer program. That is to say, the apparatus and/or the computer program may have an element to perform the corresponding method steps. Likewise, the features (and also examples) of the apparatus or of the computer program specified herein may be carried out correspondingly as method steps.

### BRIEF DESCRIPTION OF THE DRAWINGS

The detailed description that follows describes technical background information and exemplary embodiments of the invention with reference to the figures, which show the following:

FIG. 1 schematically illustrates an exemplary lithography apparatus which can be configured to carry out the method.

FIG. 2 illustrates a simulation result of a substantially undiffracted radiation of an exemplary lithography apparatus, with the substantially undiffracted radiation containing an obscured subset.

FIG. 3 illustrates simulation results of a diffracted radiation of an exemplary lithography apparatus in an exit pupil, the calculated diffracted radiation in an entrance pupil, and the determined diffraction efficiency of the diffracted radiation.

FIG. 4 illustrates simulation results of diffraction efficiencies of diffracted radiations.

FIG. 5 schematically illustrates the association of an unobscured subset of a diffracted radiation in relation to the corresponding obscured subset of a substantially diffracted radiation.

### DETAILED DESCRIPTION

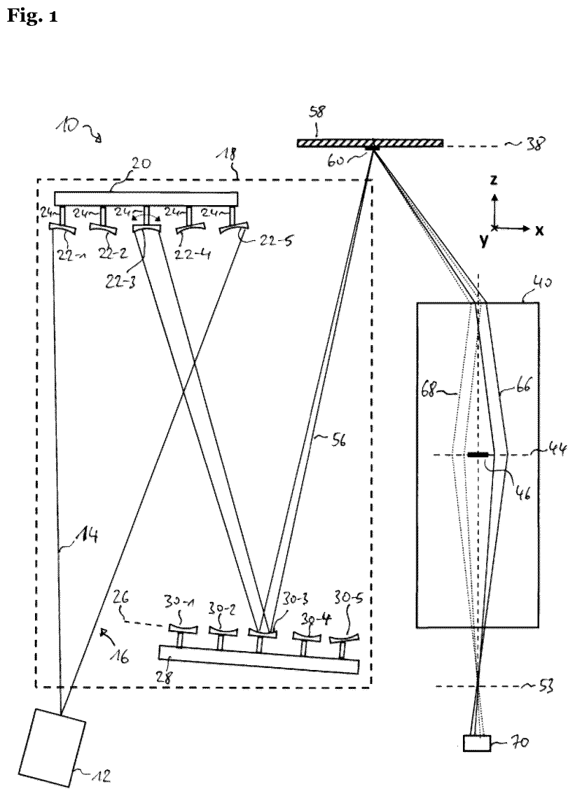

FIG. 1 schematically illustrates an exemplary lithography apparatus in a plan view. The exemplary lithography apparatus corresponds in part to FIG. 1 of DE 10 2018 207 384 A1 and may contain the details described there. To provide an overview, the exemplary lithography apparatus is explained briefly within the scope of the present application. In this case, the characterization element (as described herein) may correspond to the measurement structure 60 which can be arranged on a measurement reticle 58. The measurement reticle 58 might be aligned along a reticle plane 38 in this case. FIG. 1 illustrates a measuring mode for detecting the radiation of the lithography apparatus 10 diffracted at the measurement structure 60. With regards to the measurement structure 60, a region of incidence of radiation is present on the one hand. The radiation which can be incident on the measurement structure is based e.g. on the radiation of a beam source 12. In this case, the beam source 12 can emit an exposure radiation 14 into an illumination system 18. In this case, the illumination system 18 can also be regarded as an illumination unit. In the illumination system 18, the exposure radiation 14 can initially be incident on a first mirror 20. In this case, the first mirror 20 can comprise a plurality of first facet mirrors 22-1 to 22-5. Each facet mirror 22-1 to 22-5 may comprise an actuator 24 allowing this facet mirror to be adjusted on an individual basis, e.g. be tilted about two mutually orthogonal tilt axes. The actuators 24 can be driven by a control device.

The illumination system 18 may further comprise a second mirror 28 which can comprise a plurality of second facet mirrors 30-1 to 30-5 (the number and arrangement of five mirrors is purely by way of example), which can be arranged in a pupil plane 26. In this case, the first and second facet mirrors can be arranged in a matrix arrangement. In this case, a first facet mirror 22-3 of the first mirror 20 can selectively direct a part of the exposure radiation 14 to a (e.g. corresponding) second facet mirror 30-3 of the second mirror 28. In this case, the second facet mirror 30-3 can direct this part of the exposure radiation as a first substantially undiffracted radiation beam 56 to the measurement structure 60. Accordingly, any desired combination and number of radiation beams which are radiated into the reticle plane 38 can be formed with the plurality of first and second facet mirrors. Accordingly, the first and second facet mirrors can form different radiation channels in the illumination system 18, wherein the various radiation channels can be radiated on the measurement structure 60. The incident first substantially undiffracted radiation beam can experience a diffraction with a diffraction structure (not depicted in detail) on the measurement structure 60 (e.g. a diffraction grating). For example, the measurement structure 60 can accordingly emit a corresponding first diffracted radiation beam of plus first order 66 and a corresponding first diffracted radiation beam of minus first order 68 into the exit region. These emerging orders of diffraction and their beam paths should be considered to be schematic and exemplary. Further, a first diffracted radiation beam of the zeroth order can be emitted, and also a first diffracted radiation beam of any desired other order of diffraction, depending on the diffraction effect of the measurement structure. In this case, the diffracted radiation beams 66, 68 can be incident on a projection lens 40 of the lithography apparatus. The projection lens can image the diffracted radiation beams 66, 68 onto a wafer plane 53. In this example, the projection lens 40 comprises an obscuration 46 in an obscuration plane 44. Accordingly, the obscuration 46 can cause a radiation (e.g. a radiation beam) incident on the obscuration to not be present in the wafer plane or not be able to be detected in this region. For example, the obscuration 46 may comprise an obscuration stop which can absorb a radiation of the lithography apparatus. The first diffracted radiation beams 68, 66 are diffracted such that, in the example of FIG. 1, they propagate next to the obscuration 46 and are consequently able to be incident on the wafer plane 53. The first diffracted radiation beams 68, 66 can be detected offset in a detection plane (not explicitly depicted here), in which the detector 70 is arranged. Detection in the detection plane offset from the wafer plane can enable a detection of the first diffracted radiation 68, 66 in the distribution of an angular space (e.g. an angular space of an exit pupil). In this case, the detector can detect e.g. the intensity of the radiation.

The lithography apparatus may comprise a diffraction property determining element-as described herein. The element can be designed to obtain the corresponding input variables with an appropriately designed user interface. However, it can also be configured to automatically read out the input variables. The element can comprise e.g. a computer or a computer system. The computer and/or the computer system can further be configured to prompt the apparatus to at least partly automatically carry out one of the methods described herein.

However, for the method described herein, it is also possible to detect the first substantially undiffracted radiation (or the first substantially undiffracted radiation beam). To this end, a reflective element (e.g. a mirror element) can be arranged in the reticle plane 38 in place of the measurement structure 60. In this case, the reflective element can radiate the first substantially undiffracted radiation beam 56 at the reticle plane 38 into the optical path of the projection lens 40. Depending on the optical setting of the illumination system 18, the first substantially undiffracted radiation beam may or may not be exposed to the obscuration 46. In the case of a plurality of first substantially undiffracted radiation beams, it is accordingly possible for a subset to be exposed to the obscuration 46, while the other part of the radiation beams are not exposed to the obscuration 46, and hence are detected. The first substantially undiffracted radiation beams are henceforth also referred to as undiffracted radiation channels. Accordingly, some undiffracted radiation channels cannot be detected at the detector as a result of the obscuration.

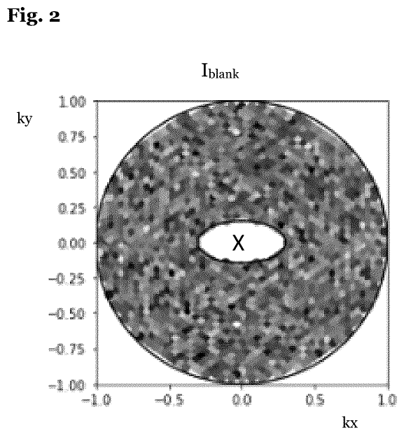

This is depicted e.g. in FIG. 2. FIG. 2 illustrates a simulation result of a substantially undiffracted radiation of an exemplary lithography apparatus, with the substantially undiffracted radiation containing an obscured subset X. In this case, the simulation result can represent the intensity distribution of the undiffracted radiation channels I_blank in the exit pupil of the lithography apparatus (e.g. the detected signal in the detection plane). In this case, the representation corresponds to the representation of the intensity in the angular space with the wave vector kx on the x-axis and the wave vector ky on the y-axis, the wave vectors specifying the exit wave vectors in relation to the reticle plane. In this case, the obscured subset X comprises undiffracted radiation channels which cannot be detected through the obscuration and accordingly are inaccessible.

However, it is helpful to also know the information from the undiffracted radiation channels comprised in the obscured subset X for the purpose of characterizing the lithography apparatus 10. In this case, FIG. 2 illustrates a pixel-structured pattern, wherein a pixel can correspond to an undiffracted radiation channel which e.g. is detected at the detector. In the simulation relating to FIG. 2, a noise was introduced via the facet mirrors in order to illustrate how deviations in the illumination system 18 (and/or the source optical unit) of the lithography apparatus may have an influence on the intensity distribution of the undiffracted radiation channels. In practice, the brightness variations in the radiation channels may also be caused e.g. by the source optical unit of the lithography apparatus. For example, these brightness variations may result from the (e.g. optical) non-idealities of the source optical unit. What may arise in this context is that these non-idealities can vary over time. The source optical unit may e.g. comprise a plasma for emitting radiation, wherein this radiation can be emitted into the illumination unit via one or more optical elements of the source optical unit (e.g. a parabolic mirror).

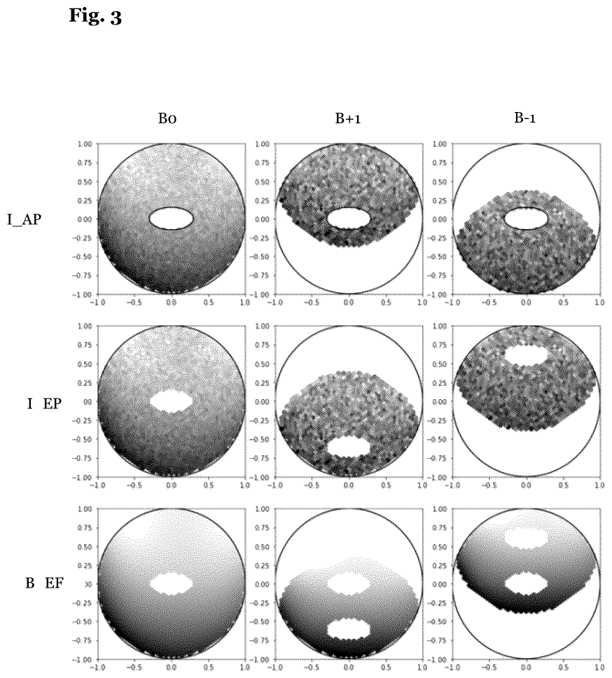

In this case, FIG. 3 illustrates simulation results of a diffracted radiation of an exemplary lithography apparatus in an exit pupil, simulation results of the calculated diffracted radiation in an entrance pupil, and the determined diffraction efficiency of the diffracted radiation. In this case, the simulation results illustrated in FIG. 3 are based on the noise and the undiffracted radiation channels from FIG. 2. In this respect, FIG. 3 can be visualized as the undiffracted radiation channels from the illumination unit being incident on the measurement structure 60 rather than a reflective element, with the result that corresponding first diffracted radiation beams are diffracted out of the measurement structure 60. These first diffracted radiation beams can be depicted in the exit pupil according to FIG. 3 and e.g. correspond to the intensity distribution in the detection plane of the detector 70. The first diffracted radiation beams are henceforth also referred to as diffracted radiation channels. Thus, the first line in FIG. 3 with the intensity distribution of the exit pupil I_AP specifies the intensities of the diffracted radiation channels for various orders of diffraction (with kx being depicted on the abscissa and ky being depicted on the ordinate). The zeroth order of diffraction B0, the plus first order of diffraction B+1 and the minus first order of diffraction B−1 of the diffracted radiation channels are depicted. Once again, the influence or the noise of the illumination unit is identifiable in the intensity distribution of the exit pupil I_AP. The obscuration 46 in the center of the intensity distribution of the exit pupil I_AP is also identifiable (the obscuration manifesting itself as a central obscuration in this case).

It should be mentioned that a position of a diffracted radiation channel of zeroth order of diffraction corresponds in angular space to the position of the corresponding undiffracted radiation channel. Further, the diffracted radiation channels e.g. of the plus first order are displaced with regards to the zeroth order, and also with regards to the corresponding undiffracted radiation channels, in terms of position in angular space (or analogously on the detector). This displacement corresponds to the displacement of the diffraction maxima of an order of diffraction differing from zero in relation to the e.g. zeroth order of diffraction. However, it is generally not possible to image all diffraction maxima on account of the numerical aperture, and so a portion of the diffraction maxima of the diffracted radiation channels are not detected, e.g. as is identifiable in FIG. 3 for the first order of diffraction B+1 and B−1. As a result of the displacement of the position of the diffracted radiation channels in the exit angular space on account of the diffraction, the (e.g. detected) diffracted radiation channels cannot readily be related to a corresponding undiffracted radiation channel. However, this must be implemented in order to determine the diffraction property. The second line of FIG. 3 thus depicts the intensity distribution of the entrance pupil I_EP. In this case, the entrance pupil represents the entrance angular space in relation to the measurement structure 60 or the plane of the measurement structure 60 (e.g. the reticle plane). The intensity distribution of the entrance pupil I_EP can e.g. take account of reflective factors, e.g. of the reflective element. In this case, a mathematical transformation can be used to convert the diffracted radiation channels into the entrance angular space. There is no displacement in the case of the zeroth order of diffraction since the angle of entrance corresponds to the exit angle in this case. However, there is a displacement in the case of the plus first order of diffraction B+1 and in the case of the minus first order of diffraction B−1, as identifiable in FIG. 3. As a result of the transformation into the entrance angular space, wave vector and radiation channel correspond for both diffracted and undiffracted radiation channels, independently of an order of diffraction. Accordingly, it is possible to compare the diffracted and undiffracted radiation channels at the same wave vector coordinates in the entrance angular space. For example, in the case of the intensity distribution of the entrance pupil I_EP, the same diffracted radiation channel for all orders of diffraction B0, B+1, B−1 is present at kx=0.5 and ky=−0.5. Likewise, the wave vector of a diffracted radiation channel corresponds to the wave vector of a corresponding undiffracted radiation channel in this case, with the result that the intensity distribution I_blank of the undiffracted radiation channels of FIG. 2 can be compared at the same coordinates to the intensity distribution of the diffracted radiation channels in the entrance angular space. Likewise, a diffracted radiation channel in the entrance pupil can be compared with an undiffracted radiation channel at the same coordinate. Accordingly, the diffracted radiation can be related to the undiffracted radiation in order to determine the diffraction property of the measurement structure 60. For example, the diffraction efficiency B_EF is specified in the third line of FIG. 3; it corresponds to the ratio of the intensity of the diffracted radiation channel to the intensity of the corresponding undiffracted radiation channel. Accordingly, it is evident that the central obscuration is identifiable again in the case of the zeroth order of diffraction B0 since the position of a diffracted radiation channel of zeroth order corresponds to the position of the undiffracted radiation channel in the entrance and exit angular space. However, two undefined regions in the diffraction efficiency arise for the first orders of diffraction, as identifiable in FIG. 3. This is related to the fact that the obscured undiffracted radiation channels do not correspond to the obscured diffracted radiation channels (which may arise due to the displacement of the diffraction maxima). For example, a first undefined region therefore arises in the region of kx=ky=0 for the order of diffraction B+1, which arises due to the obscured undiffracted radiation channels. Further, a second undefined region arises by way of example in the region of kx=0, ky=−0.6 for the order of diffraction B−1, which arises due to the obscured diffracted radiation channels. Accordingly, the diffraction efficiencies for lithography apparatuses with an obscuration may be incomplete.

Further, it should be observed that the influence of the illumination unit lessens when the diffraction efficiency is formed since the intensities of corresponding radiation channels are divided by one another. A noise which could be comprised in the illumination unit accordingly has no influence on the correct determination of the diffraction property.

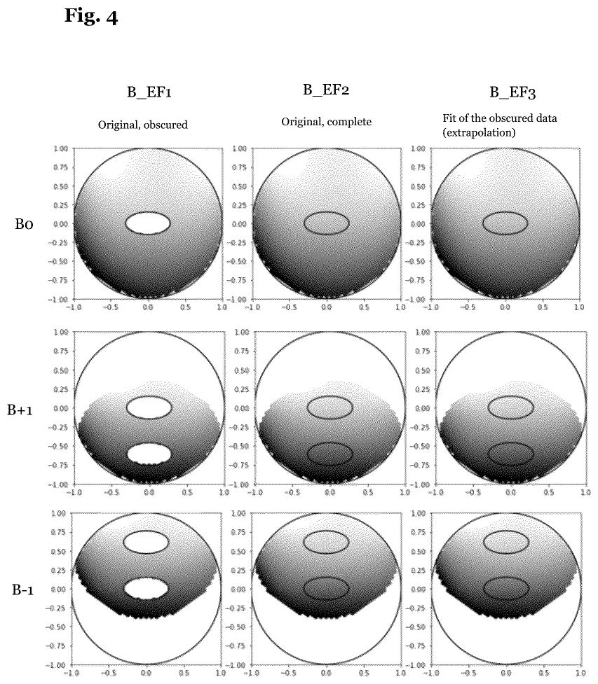

In this case, FIG. 4 illustrates simulation results of diffraction efficiencies of diffracted radiations. In this case, the first column in FIG. 4 corresponds to the diffraction efficiency B_EF1, which is depicted for the diffracted radiation channels of the zeroth order of diffraction B0, the plus first order of diffraction B+1 and the minus first order of diffraction B−1. In this case, the first column of FIG. 4 corresponds to the third line of FIG. 3. Accordingly, this depicts the incomplete diffraction efficiencies caused by the obscuration. The second column in FIG. 4 likewise specifies a diffraction efficiency B_EF2 of the orders of diffraction. However, the influence of the obscuration was removed during the simulation in this case. Thus, the determination of the diffraction efficiency B_EF2 was based on complete information. In this simulation case, the intensity distributions of the undiffracted and diffracted radiation channels did not have regions with obscuration. The third column depicts a diffraction efficiency B_EF3 of the orders of diffraction, wherein in this case the diffraction efficiency was compensated (as described herein) for the undefined region or regions of the obscuration from the first column of the diffraction efficiency B_EF1. Subsequently, the diffraction efficiency B_EF2 without obscuration could be compared to the diffraction efficiency B_EF3, in which an obscuration appearance was compensated. As evident from FIG. 4, no difference is identifiable between the diffraction efficiencies B_EF2 and the diffraction efficiency B_EF3. Accordingly, the compensation can sufficiently enable the determination of the diffraction efficiency (or the determination of the diffraction property). Inter alia, this is enabled by the continuity of the diffraction property. However, it is also conceivable that discontinuities of the diffraction property may arise in the general case. In this case, however, the structure on the measurement reticle can be chosen (or designed) such that the discontinuity is suppressed (e.g. in the case of a diffraction grating as a structure).

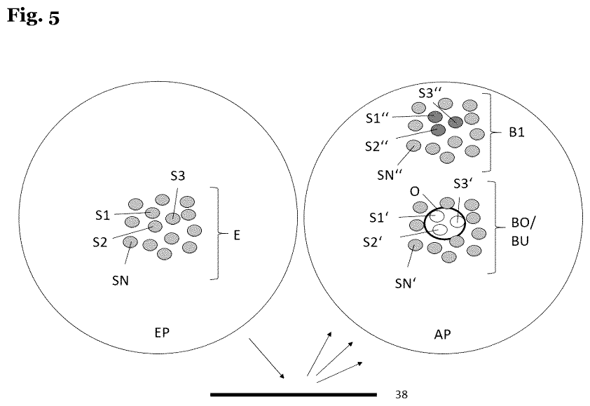

FIG. 5 schematically illustrates the association of an unobscured subset of a diffracted radiation in relation to the corresponding obscured subset of a substantially undiffracted radiation. As described herein, the diffraction property can be used to determine the obscured subset of the undiffracted radiation or undiffracted radiation beams. In this case, FIG. 5 schematically shows the intensity spots of the undiffracted radiation beams E in the entrance pupil EP (or in the entrance angular space) in relation to the reticle plane 38 which causes a diffraction and in which e.g. the measurement structure 60 (or the characterization element) can be arranged. In this case, the undiffracted radiation beams E irradiate the measurement structure 60 (not depicted in FIG. 5) and are diffracted out of the reticle plane 38 such that corresponding diffracted radiation beams are radiated into the projection lens of the lithography apparatus. Some of these diffracted radiation beams may have been exposed to the obscuration of the lithography apparatus in the case. Further, the exit pupil AP (or the exit angular space) is depicted, which detects the diffracted radiation beams downstream of the obscuration. In this case, e.g. diffracted radiation beams corresponding to the zeroth order of diffraction B0 or the first order of diffraction B1 are identifiable in the exit pupil. In this case, the position of the diffracted radiation beams of the zeroth order of diffraction B0 can also correspond to the position of the undiffracted radiation beams BU, which were radiated purely reflectively into the projection lens without diffraction at the measurement structure. The obscuration O results in some undiffracted radiation beams S1′, S2′, S3′ being undetectable in the exit pupil even though the corresponding radiation beams S1, S2, S3 were present in the entrance pupil. The undiffracted radiation beams exposed to the obscuration can be referred to here as obscured undiffracted radiation beams S1′, S2′, S3′. According to the invention, these can be determined with the diffraction property (as described herein). Within the scope of the method (described herein), it might e.g. be determined that, as they are detected, corresponding unobscured diffracted radiation beams S1″, S2″, S3″ (e.g. of the first order of diffraction B1) are present for the obscured undiffracted radiation beams S1′, S2′, S3′. The obscured undiffracted radiation beams S1′, S2′, S3′ can be considered to be the obscured subset while the unobscured diffracted radiation beams S1″, S2″, S3″ are in this case associated via an order of diffraction with the obscured subset. Further, e.g. the position of the obscured undiffracted radiation beams S1′, S2′, S3′ can be determined with the method (described herein). To this end, it is possible to use e.g. an unobscured undiffracted radiation beam SN′ and/or a corresponding unobscured diffracted radiation beam SN″ e.g. from the surroundings of the obscuration. According to the invention, the diffraction property can be determined for all diffracted radiation beams with the compensation. Accordingly, the diffraction property for the unobscured diffracted radiation beams S1″, S2″, S3″ is available and can be correspondingly used to determine the intensity of the obscured undiffracted radiation beams S1′, S2′, S3′. For example, the intensity of the obscured undiffracted radiation beams S1′, S2′, S3′ can be determined with the ratio of the intensity of the corresponding unobscured diffracted radiation beams S1″, S2″, S3″ divided by their diffraction efficiency (or diffraction property).

What is claimed is:

1. A method for characterizing a lithography apparatus configured to cause an obscuration of radiation, comprising:
detecting a first substantially undiffracted radiation of the lithography apparatus;
detecting a first diffracted radiation of the lithography apparatus, the first diffracted radiation having been diffracted at a characterization element;
determining a diffraction property of the characterization element, based at least in part on the first substantially undiffracted radiation and the first diffracted radiation.

2. The method as claimed in claim 1, wherein said determining of the diffraction property is based further on a compensation.

3. The method as claimed in claim 2, wherein the compensation compensates an appearance of the diffraction property associated with the obscuration.

4. The method as claimed in claim 2, wherein the compensation comprises an interpolation and/or an extrapolation.

5. The method as claimed in claim 1, wherein the diffraction property is based at least in part on a relationship of the first diffracted radiation to the first substantially undiffracted radiation.

6. The method as claimed in claim 1, wherein the diffraction property comprises a diffraction efficiency of the first diffracted radiation in relation to the first substantially undiffracted radiation in an angular space.

7. The method as claimed in claim 1, wherein said detecting of the first substantially undiffracted radiation comprises detecting an intensity of the first substantially undiffracted radiation in a pupil of the lithography apparatus; and/or
wherein said detecting of the first diffracted radiation comprises detecting an intensity of the diffracted radiation in the pupil.

8. The method as claimed in claim 1, wherein the first substantially undiffracted radiation comprises a plurality of first substantially undiffracted radiation beams; and
wherein the first diffracted radiation comprises a plurality of first diffracted radiation beams, each of which was diffracted at the characterization element.

9. The method as claimed in claim 1, wherein said determining of the diffraction property comprises determining at least one order of diffraction of the first diffracted radiation.

10. The method as claimed in claim 8, wherein said determining of the diffraction property comprises determining at least one order of diffraction of the first diffracted radiation; and
wherein the order of diffraction is determined for at least one first diffracted radiation beam from the plurality of diffracted radiation beams.

11. The method as claimed in claim 10, wherein a corresponding first substantially undiffracted radiation beam from the plurality of first substantially undiffracted radiation beams is determined for the at least one first diffracted radiation beam.

12. The method as claimed in claim 11, wherein the diffraction property is determined for the at least one first diffracted radiation beam.

13. The method as claimed in claim 1, wherein the lithography apparatus is configured such that a subset of the first substantially undiffracted radiation is exposed to the obscuration and thereby forms an obscured subset.

14. The method as claimed in claim 13, further comprising determining at least one part of the obscured subset, based at least in part on the diffraction property and the first diffracted radiation.

15. The method as claimed in claim 13, wherein the lithography apparatus is further configured such that a subset of the first diffracted radiation is not exposed to the obscuration and thereby forms an unobscured subset.

16. The method as claimed in claim 14, wherein the lithography apparatus is further configured such that a subset of the first diffracted radiation is not exposed to the obscuration and thereby forms an unobscured subset; and
wherein said determining of the obscured subset part is also based at least in part on the part of the unobscured subset which is associated via an order of diffraction with the part of the obscured subset.

17. The method as claimed in claim 16, wherein said determining of the obscured subset part further comprises:
determining at least one first substantially undiffracted radiation beam comprised in the obscured subset, based at least in part on a corresponding first diffracted radiation beam of at least one order of diffraction comprised in the unobscured subset.

18. The method as claimed in claim 17, wherein said determining of the obscured subset part further comprises:
determining an intensity of the at least one first substantially undiffracted radiation beam based at least in part on the diffraction property and the intensity of the corresponding first diffracted radiation beam.

19. The method as claimed in claim 1, further comprising:
detecting a second substantially undiffracted radiation of the lithography apparatus;
detecting a second diffracted radiation of the lithography apparatus, the second diffracted radiation having been diffracted at the characterization element; and
determining a subset of the second substantially undiffracted radiation which is exposed to the obscuration, based at least in part on the diffraction property and the second diffracted radiation.

20. The method as claimed in claim 19, wherein the second substantially undiffracted radiation is associated with a beam path of the first substantially undiffracted radiation, with the second diffracted radiation being associated with a beam path of the first diffracted radiation.

21. The method as claimed in claim 13, further comprising adjusting a radiation emitting element of the lithography apparatus, based at least in part on said determining of the obscured subset of the first substantially undiffracted radiation.

22. The method as claimed in claim 1, wherein the characterization element is arranged in a reticle plane of the lithography apparatus.

23. The method as claimed in claim 1, wherein the characterization element comprises a diffraction structure.

24. The method as claimed in claim 1, wherein the obscuration is associated with a radiation projecting element of the lithography apparatus and/or an obscuration stop of the lithography apparatus.

25. The method as claimed in claim 1, wherein the first substantially undiffracted radiation comprises radiation reflected at a reticle plane of the lithography apparatus; and/or
wherein the first diffracted radiation comprises radiation diffracted at the reticle plane.

26. A lithography apparatus, comprising:
a radiation detecting element;
a diffraction property determining element of a characterization element, wherein the lithography apparatus is configured to perform a method as claimed in claim 1.

27. The lithography apparatus as claimed in claim 26, wherein the lithography apparatus is configured to carry out the method automatically.

28. A non-transitory computer readable medium comprising instructions which, when executed by a computer apparatus and/or a lithography apparatus, cause the computer apparatus and/or the lithography apparatus to carry out the method as claimed in claim 1.

29. The lithography apparatus comprising a memory storing a computer program comprising the instructions as claimed in claim 28.

30. The method as claimed in claim 19, further comprising adjusting a radiation emitting element of the lithography apparatus, based at least in part on said determining of the subset of the second substantially undiffracted radiation.
